(19) United States
(12) Patent Application Publication
(10) Pub. No.: US 2026/0363044 A1
(43) Pub. Date: Nov. 12, 2026

(54) HIGH-THROUGHPUT SELECTIVE MO PROCESS AT LOW TEMPERATURE WITH SINGLE GRAIN GROWTH IN BEOL

(71) Applicant: Applied Materials, Inc., Santa Clara, CA (US)

(72) Inventors: Yu-Heng DENG, Santa Clara, CA (US); Jiajie CEN, Santa Clara, CA (US); Ya-Hsi HWANG, Santa Clara, CA (US); Shiyu HU, Santa Clara, CA (US); Ruinan ZHOU, Santa Clara, CA (US)

(21) Appl. No.: 19/202,186

(22) Filed: May 8, 2025

(51) Int. Cl. H10W 20/00; H10P 14/40

(52) U.S. Cl. CPC H10W 20/045; H10P 14/412; H10W 20/056

(57) ABSTRACT

A method includes forming a nucleation layer on at least one electrical connection formed in a feature formed within a dielectric layer of a semiconductor device structure. The method further includes forming a metal fill material over the nucleation layer and within the feature using a deposition process including flowing a molybdenum-containing precursor at a precursor gas flow rate, a reducing agent at a reducing agent gas flow rate, and a carrier gas at a carrier gas flow rate into a processing region during a first period of time, and stopping the flowing of the molybdenum-containing precursor after the first period of time while continuing the flowing of the reducing agent and the carrier gas during a second period of time.

### BACKGROUND

### Field

Embodiments described herein generally relate to semiconductor device fabrication. More specifically, embodiments of the present disclosure relate to semiconductor devices that includes low resistance contacts and methods of forming the same.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., Dynamic Random Accede Memory (DRAM)) and logic devices, including both planar and three-dimensional structures. Examples of three-dimensional structures are Fin Field Effect Transistor (finFET) and Metal-Oxide Field Effect Transistor (MOSFET) devices.

In a traditional middle-of-the-line (MOL) interconnect formation process, a feature, such as a via or trench is fabricated in the semiconductor substrate. MOL contacts allow connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Conventional MOL and BEOL electrical connections, such as contacts, interconnects, and the like are formed by filling a feature such as a cavity, trench, or via with a conductive material. Then the feature is filled with a metal material to form a metal fill layer that serves as an interconnect between layers of the device. As devices reach the 1.4 nm node and beyond, molybdenum is being used to replace tungsten as the material of the metal fill layer due to its lower resistivity inside smaller features. However, molybdenum precursors used to deposit molybdenum have a corrosive property that causes corrosion of the conductive material within the feature.

Therefore, there is a need for using molybdenum-fill material to form electrical connections without causing corrosion of the conductive material.

### SUMMARY

According to one or more embodiments, a method includes forming a nucleation layer on at least one electrical connection formed in a feature formed within a dielectric layer of a semiconductor device structure, forming a metal fill material over the nucleation layer and within the feature using a deposition process including flowing a molybdenum-containing precursor at a precursor gas flow rate, a reducing agent at a reducing agent gas flow rate, and a carrier gas at a carrier gas flow rate into a processing region during a first period of time, and stopping the flowing of the molybdenum-containing precursor after the first period of time while continuing the flowing of the reducing agent and the carrier gas during a second period of time.

According to one or more embodiments, a method includes forming a nucleation layer on at least one electrical connection formed in a feature formed within a dielectric layer of a semiconductor device structure, forming a metal fill material over the nucleation layer and within the feature using a deposition process including flowing a molybdenum-containing precursor, a reducing agent at a reducing agent gas flow rate, and a carrier gas at a carrier gas flow rate into a processing region during a first period of time, wherein flowing the molybdenum-containing precursor includes switching between a first ampoule temperature and a second ampoule temperature while the processing region is maintained at a constant chamber pressure, and the second ampoule temperature is greater than the first ampoule temperature, and stopping the flowing of the molybdenum-containing precursor after the first period of time while continuing the flowing of the reducing agent and the carrier gas during a second period of time.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber substrate processing system in accordance with one or more embodiments described herein.

FIG. 2 illustrates a process flow diagram for a method of manufacturing a semiconductor device in accordance with one or more embodiments described herein.

FIGS. 3A-3D illustrate views of various stages of manufacturing a semiconductor device in accordance with one or more embodiments described herein

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Middle-of-the-line (MOL) and back-end-of-the-line (BEOL) electrical connections, such as interconnects, and the like are formed by filling a feature such as a cavity, trench, or via with a metal fill material that is in contact with a conductive material (defined herein as an electrical connection). Molybdenum is currently replacing tungsten as the material of the metal fill material due to its lower resistivity inside smaller features. However, molybdenum precursors used to deposit molybdenum have a corrosive property that causes corrosion of the conductive material within the feature. Embodiments herein relate to a using molybdenum-fill material to form electrical connections without causing corrosion of the conductive material.

### Example Multi-Chamber Processing System

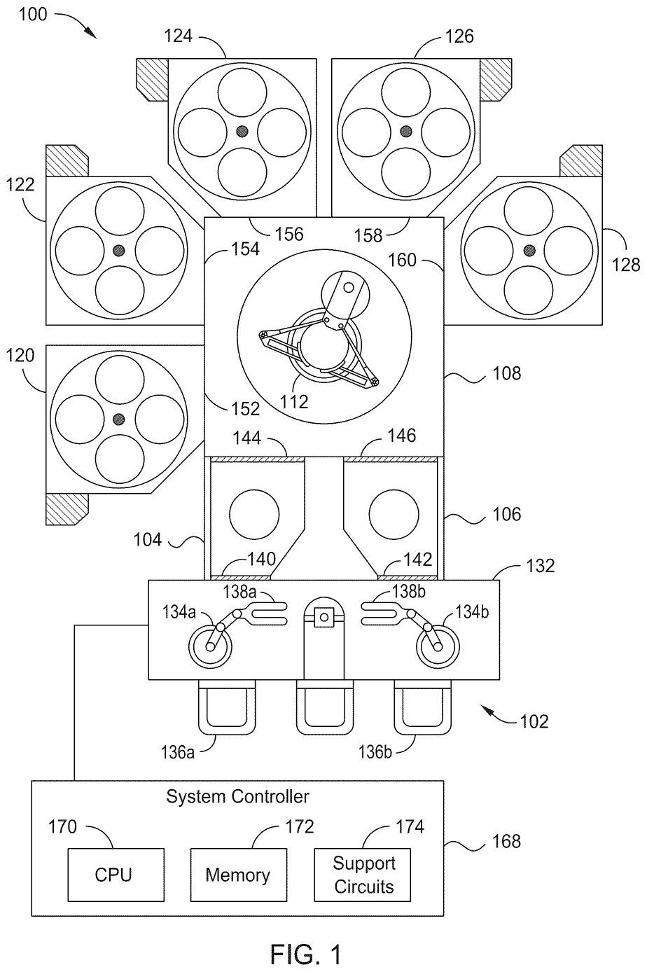

FIG. 1 illustrates a schematic top view of a multi-chamber substrate processing system 100 in accordance with one or more embodiments of the present disclosure. The substrate processing system 100 can be used for deposition of a seamless fill of molybdenum from the bottom of a feature, upward to the top of the feature, without breaking vacuum in accordance with one or more embodiments of the present disclosure. The substrate processing system 100 generally includes a factory interface 102, load lock chambers 104, 106, a transfer chamber 108, with a transfer robot 112, and processing chambers 120, 122, 124, 126, and 128. As detailed herein, substrates in the substrate processing system 100 can be processed in and transferred between the various chambers without exposing the substrates to an ambient environment exterior to the substrate processing system 100, for example, an atmospheric ambient environment such as may be present in a fab. The substrates can be processed in and transferred between the various chambers maintained at a low pressure, or a vacuum environment without breaking the low pressure or vacuum environment among various processes performed on the substrates in the substrate processing system 100. For example, the low pressure the substrates may be processed in is about 0.01 Torr to less than or equal to about 760 Torr, such as about 300 Torr. Accordingly, the substrate processing system 100 may provide for an integrated solution for processing of substrates.

Alternate examples of processing systems that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 has respective ports 152, 154, 156, 158, and 160 coupled to processing chambers 120, 122, 124, 126, and 128. The ports 144, 146, 152, 154, 156, 158, and 160, can be, for example, slit valve openings with slit valves for passing substrates through by the transfer robot 112, and for providing a seal between respective chambers to prevent a gas from passing between the respective chambers. Generally, any port is open for transferring a substrate therethrough. Otherwise, the port is closed.

The load lock chambers 104, 106, the transfer chamber 108, and the processing chambers 120, 122, 124, 126, and 128, may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chamber 108 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122, 124, 126, and 128, through the respective ports 152, 154, 156, 158, and 160 for processing. The transfer and holding of the substrate within and among the various chambers can be in the low pressure or vacuum environment provided by the gas and pressure control system.

The processing chambers 120, 122, 124, 126, and 128 include multiple processing stations disposed within a common processing region. The processing chambers 120, 122, 124, 126, and 128, can be any appropriate chamber for processing a substrate. In some examples, the processing chamber 120 can be capable of performing an etch process, the processing chamber 122 can be capable of performing a cleaning process, and the processing chambers 126, and 128, can be capable of performing respective growth (e.g., deposition) processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, or 128, may be a Centura™ Epi chamber, Volta™ CVD/ALD chamber, or Encore™ PVD chambers available from Applied Materials of Santa Clara, Calif.

A system controller 168 is coupled to the substrate processing system 100 for controlling the substrate processing system 100 or components thereof. For example, the system controller 168 may control the operation of the substrate processing system 100 using a direct control of the processing chambers 104, 106, 108, 120, 122, 124, 126, and 128, of the substrate processing system 100 or by controlling controllers associated with the processing chambers 104, 106, 108, 120, 122, 124, 126, and 128. In operation, the system controller 168 enables data collection and feedback from the respective chambers to coordinate performance of the substrate processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure. The system controller 168 is configured to perform methods such as the method 200 stored in the memory 172.

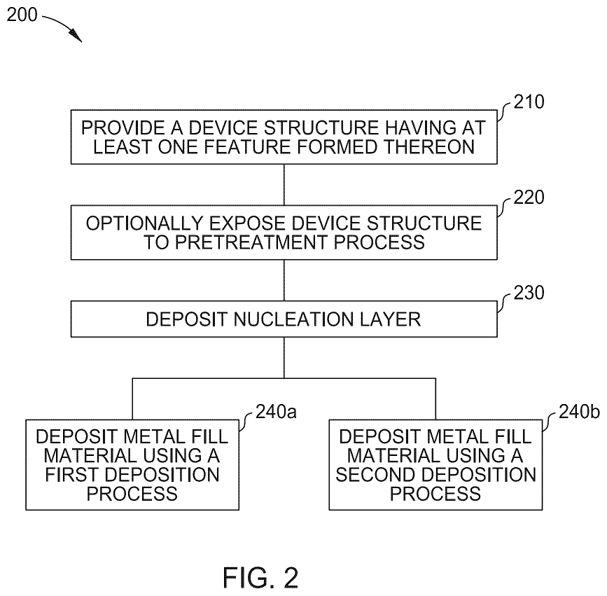

In particular embodiments, at least one of the processing chambers 120 and 122 is a pre-clean chamber configured to perform a pretreatment process of operation 220, at least one of the processing chambers 124, 126, or 128, is a chemical vapor deposition (CVD) chamber configured to perform the molybdenum deposition processes of operations 230, 240a, and 240b of a method 200 without breaking vacuum between any of the operations of the method 200 (FIG. 2).

In operation, a substrate having a feature formed therein may be transferred to a first processing chamber which is one of the processing chambers 122 and 124 where the feature is exposed to a pretreatment process to remove, or clean, for example, native oxides formed on the feature. The substrate may then be transferred to a second processing chamber which is one of the processing chamber 124, 126, and 128, without breaking vacuum where a metal layer, for example, a molybdenum layer, is deposited over the feature. The substrate may then be transferred to a third processing chamber which is one of the processing chambers 126, and 128, and without breaking vacuum, for additional processing. Other processing systems can be in other configurations.

### Processing Sequence Example

FIG. 2 illustrates a process flow diagram for a method 200 of manufacturing a semiconductor device in accordance with one or more embodiments described herein.

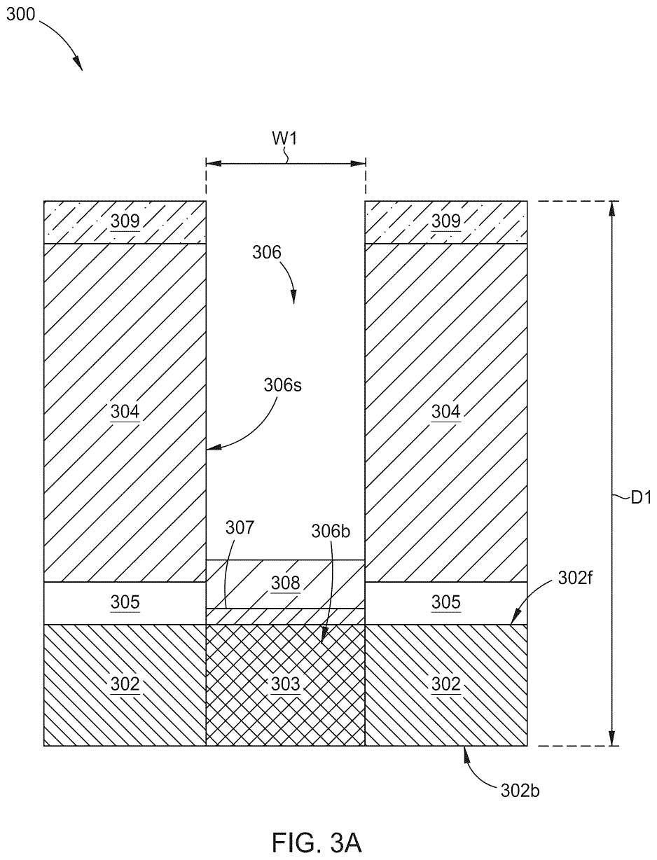

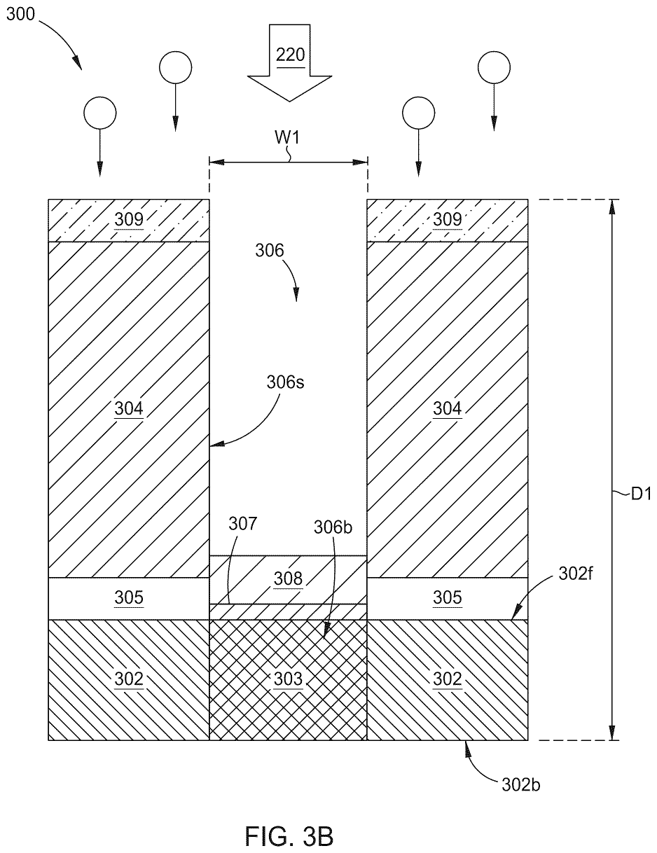

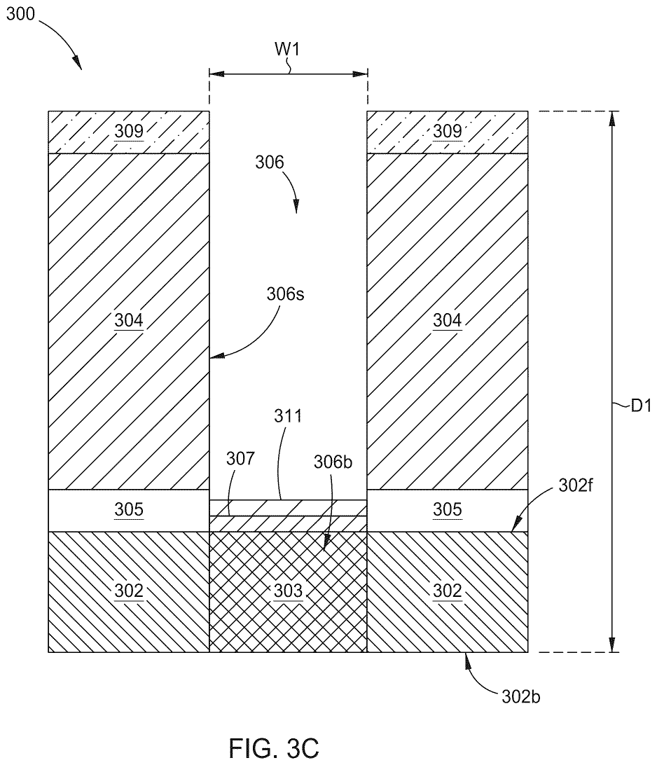

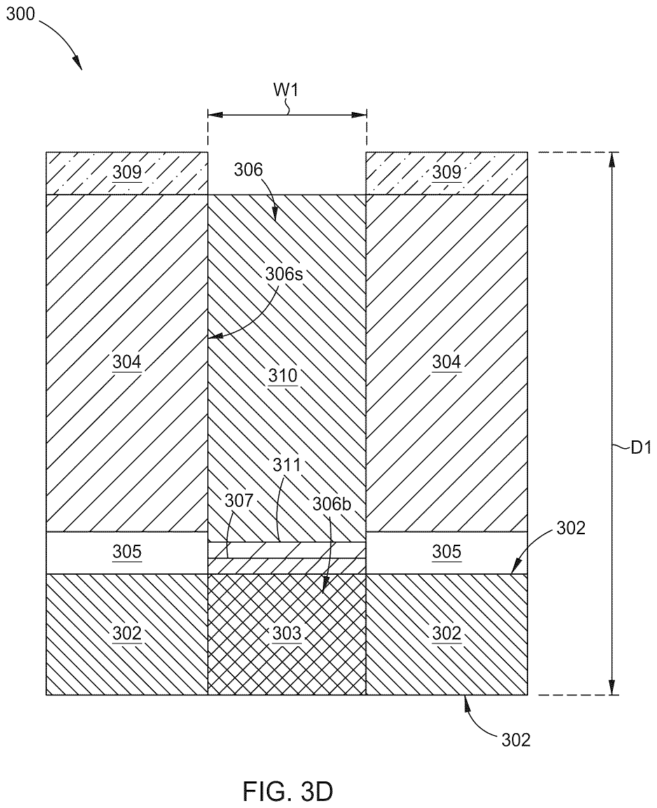

FIGS. 3A-3D illustrate views of various stages of manufacturing a semiconductor device 300 in accordance with one or more embodiments described herein. Although FIGS. 3A-3D are described in relation to the method 200, the structures disclosed in FIGS. 3A-3D are not limited to the method 200, but instead may stand alone as structures independent of the method 200. Similarly, although the method 200 is described in relation to FIGS. 3A-3D, the method 200 is not limited to the structures disclosed in FIGS. 3A-3D but instead may stand alone independent of the structures disclosed in FIGS. 3A-3D. It should be understood that FIGS. 3A-3D illustrate only partial schematic views of the semiconductor device structure 300, and the semiconductor device structure 300 may contain any number of transistor sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100>or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 210, a semiconductor device structure 300 having a feature formed therein is provided. FIG. 3A illustrates a cross-sectional view of the semiconductor device structure 300 during intermediate stages of manufacturing corresponding to the operation 210. The semiconductor device structure 300 includes a device substrate 302 having one or more layers formed thereon, for example, dielectric layers 304 and 309, metal layer 307, etch stop layer 305, and electrical connection 303. In one or more embodiments, the dielectric layer 309, the etch stop layer 305, and the metal layer 307 are optional. The device substrate 302 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The device substrate 302 has a frontside 302f (also referred to as a front surface) and a backside 302b (also referred to as a back surface) opposite the frontside 302f. The dielectric layers 304 and 309, the etch stop layer 305, and the metal layer 307 are formed over the frontside 302f of the device substrate 302. In one or more embodiments, the etch stop layer 305 is formed between the device substrate 302 and the dielectric layers 304 and 309. The dielectric layers 304 and 309 may include multiple layers. In some embodiments, the dielectric layers 304 and 309 include a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the dielectric layers 304 and 309 consist essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio. In one or more embodiments, the etch stop layer 305 includes any suitable material, including but not limited, silicon nitride, silicon carbide, metal oxide, or carbon containing, or combinations thereof.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature is a trench. In other particular embodiments, the feature 306 is a via. In some embodiments, the feature 306 extends from the dielectric layer 309 towards the backside 302b of the device substrate 302. The feature 306 includes sidewall surface(s) 306s that extend from the dielectric layer 309 to the backside 302b.

In some embodiments, an electrical connection, such as electrical connection 303 is formed within the feature 306. The electrical connection 303 may be an interconnect, a contact structure, or the like. The electrical connection 303 may be formed by depositing a first conductive material into the feature 306. The first conductive material may be deposited such that the first conductive material fills the entire or at least a portion of the feature 306. For example, as shown in FIG. 3A, the electrical connection 303 may be a contact structure formed by filling a bottom portion 306b of the feature 306 with the first conductive material. In some embodiments, the bottom portion 306b is defined by (extends between) the frontside 302f and the backside 302b of the device substrate 302. Therefore, the electrical connection 303 may extend between the frontside 302f and the backside 302b of the device substrate 302 (or any other portion of the feature 306, including the entire feature 306). The first conductive material may be formed of copper (Cu), cobalt (Co), molybdenum (Mo), tungsten (W), or ruthenium (Ru). The feature 306 has a first depth “D1” from the dielectric layer 309 to the backside 302b and a width “W1” between the two sidewall surface(s) 306s. In some embodiments, the depth D1 is about 60 nm to about 100 nm. In some embodiments, the width W1 is about 15 nm to about 40 nm. In some embodiments, the feature 306 has an aspect ratio (D/W) of about 1 to 20.

In one or more embodiments, the metal layer 307 may formed by depositing a second conductive material over the electric connection 303. The second conductive material may different or the same as the first conductive material. The metal layer 307 is deposited in a manner such that the second conductive material fills a small portion of the feature 306.

Although the semiconductor device structure 300 includes one feature 306 this is for example purposes only. It is understood, that the semiconductor device structure 300 can include any suitable quantity of features, and that each of the features may have the same or different dimensions (sizes).

In some embodiments, as shown in FIG. 3A, the semiconductor device structure 300 may have a native oxide layer 308 or other contaminants formed on the sidewall surface(s) 306s, a top surface of the electrical connection 303 (the exposed surface of the electrical connection 303 within the feature 306), or both the sidewall surface(s) 306s and the bottom portion 306b of the feature 306. The semiconductor device structure 300 may be exposed to atmosphere prior to or during processing, which may lead to the formation of the native oxide layer 308. For example, if a vacuum break occurs prior to or during the method 200 (described below), the vacuum break can lead to the formation of native oxides. In addition, other processes performed prior to or during the method 200 may lead to the formation of additional contaminants or debris on the sidewall surface(s) 306s and the top surface 303a of the electrical connection 303.

Referring to FIG. 2, at optional operation 220, the semiconductor device structure 300 is exposed to a pretreatment process. FIG. 3B illustrates a cross-sectional view of a semiconductor device structure 300 during intermediate stages of manufacturing corresponding to the operation 220. The pretreatment process of operation 220 can include one or more native oxide or contamination removal processes for removing the contamination and/or native oxide layer 308 (if present). The pretreatment process of operation 220 can include one more clean processes. Any suitable clean process may be performed. The clean process may include a degassing process and/or a plasma treatment process.

In one or more embodiments, which can be combined with other embodiments, the feature 306 is exposed to a plasma treatment process and/or a degas process. The clean process may be performed in a processing chamber positioned on a cluster tool, for example, the substrate processing system 100 (see FIG. 1).

In one or more embodiments which can be combined with other embodiments, the pre-treatment includes a degas process followed by a plasma treatment process. The degas process removes impurities from the exposed surfaces of the semiconductor device structure 300. The plasma treatment process etches (removes) the native oxide layer 308. The plasma treatment process can be an inductively coupled plasma (ICP) process or a capacitively coupled plasma (CCP) process. The plasma can be formed ex-situ in a remote plasma source (RPS). The plasma can be a direct plasma formed in-situ, for example, generated within a processing region. In one or more embodiments, which can be combined with other embodiments, the plasma treatment process includes exposing the semiconductor device structure 300 to a plasma formed from a process gas including a hydrogen-containing gas. In one or more embodiments, which can be combined with other embodiments, the plasma treatment process includes exposing the semiconductor device structure 300 to a plasma formed from a process gas including both a hydrogen-containing gas and an oxygen-containing gas. In one example, the plasma treatment process includes exposing the feature 306 to an ICP formed from a process gas including a hydrogen-containing gas and an oxygen-containing gas. The process gas may further include an inert gas, for example, argon (Ar), helium (He), krypton (Kr), or a combination thereof. In one or more embodiments, which can be combined with other embodiments, the plasma treatment process includes exposing the feature 306 to a plasma formed from a process gas including one or more of H₂, O₂, Ar, or a combination thereof. In one or more embodiments, which can be combined with other embodiments, the plasma treatment process can include exposing the feature 306 to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In one or more embodiments, which can be combined with other embodiments, the plasma treatment process is performed at temperatures of 400 degrees Celsius or less. In one or more embodiments, which can be combined with other embodiments, the plasma treatment process includes supplying a processing gas including H₂% greater than or equal to 5% of the total flow of hydrogen and oxygen.

Referring to FIG. 2, at operation 230, and as shown in FIG. 3C, a nucleation layer 311 is formed within the feature. FIG. 3C illustrates a cross-sectional view of the semiconductor device structure 300 during intermediate stages of manufacturing corresponding to operation 230. The nucleation layer 311 is formed over the metal layer 307. The nucleation layer 311 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. In some embodiments, the nucleation layer 311 includes molybdenum. In other embodiments, the nucleation layer 311 can be a metal selected from a group consisting of tungsten (W), cobalt (Co), copper (Cu), ruthenium (Ru), and other useful metals.

In one or more embodiments, the nucleation layer 311 is deposited using a CVD process that includes cycling between a soaking process, a purge process, and a hydrogen baking process to form the nucleation layer 311. In or more embodiments, the soaking process includes soaking the semiconductor device structure 300 in a molybdenum-containing precursor gas within a processing region (as described in FIG. 1). In one example, molybdenum-containing precursor gas used during the soaking process may include molybdenum-containing precursors selected from molybdenum chlorides (e.g., MoClₓ [x=2-6]), molybdenum fluorides (MoF₆)). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum-containing nucleation layer.

The purge process includes purging the molybdenum-containing precursor from the processing region between the soaking process and the hydrogen bake by flowing a purge gas (an inert gas) into the processing region such as argon, nitrogen, or the like. After the purge process, the hydrogen baking process performed at a temperature from about 300 °C to about 450 °C, for example from about 350 °C to about 400 °C.

Referring to FIG. 2, after operation 230 the method 200 proceeds to operation 240a or operation 240b. At operation 240a, the feature 306 is filled with metal fill material 310 using a first deposition process. At operation 240b, the feature is filled with metal fill material 310 using a second deposition process. FIG. 3D illustrates a cross-sectional view of the semiconductor device structure 300 during intermediate stages of manufacturing corresponding to operation 240a and operation 240b. In one or more embodiments, the metal fill material 310 is formed over the nucleation layer 311. In one or more embodiments, the metal fill material 310 is molybdenum. In other embodiments, the metal fill material 310 is tungsten (W), or ruthenium (Ru), or any other suitable metal fill material.

The metal fill material 310 can be formed by bottom-up growth or conformal growth. For example, in operation 240a and operation 240b, the metal fill material 310 is formed by a bottom-up deposition process. In some embodiments, where one or more layers are formed on the sidewall surface(s) 306s and the metal layer 307 prior to the metal fill material 310, the metal fill material 310 may be formed by conformal growth. In some embodiments, where one or more layers are formed on the sidewall surface(s) 306s and the metal layer 307 prior to the metal fill material 310, the metal fill material 310 may formed by bottom-up growth.

In one or more embodiments, the first deposition process (operation 240a) may be any suitable deposition process such as an ALD process, a CVD process, a hybrid ALD/CVD process, a PEALD process, a PECVD process, or the like. In one example, the first deposition process includes depositing the metal fill material 310 using a CVD process including concurrently flowing (co-flowing) a molybdenum-containing precursor gas, a reducing agent, and a carrier gas into a processing region (i.e., a processing chamber) and exposing the semiconductor device structure 300 thereto. The molybdenum-containing precursor, the reducing agent, and the carrier gas used for the molybdenum-fill CVD process may include any combination of the molybdenum-containing precursors reducing agents, and carrier gases described herein. In particular embodiments, the molybdenum-containing precursor includes any of the molybdenum-containing precursor described above. The reducing agent precursor includes a hydrogen-containing gas, molecular hydrogen (H₂), hydrogen excited species, hydrogen plasma, hydrogen radicals, or combination thereof, and the carrier gas includes any suitable carrier gas (or inert gas) such as argon, nitrogen, or the like.

The metal fill material 310 fills feature 306 from the nucleation layer 311, continuing upward towards the top of the dielectric layer 309. In some embodiments, the metal fill material 310 may only partially fill the feature 306.

In one or more embodiments, the first deposition process includes repeating cycles of co-flowing the molybdenum-containing precursor gas, the reducing agent, and the carrier gas. In each cycle of the first deposition process, the duration that the molybdenum-containing precursor gas is flowed and the duration that the reducing agent and carrier gas are flowed are different. Each cycle includes a first period of time and a second period of time. During the first period of time, the molybdenum-containing precursor, the reducing agent, and the carrier gas are each flowed into the processing region. At the end of the first period of time, flow of the molybdenum-containing precursor is stopped, and during the second period of time the reducing agent and the carrier gas are still flowed into the processing region. Each cycle ends at the end of the second period of time. Thus, the duration of each cycle is equal to the sum of the first period of time and the second period of time. The first period of time is about 0.3 seconds to about 4.5 seconds, for example 3.5 seconds. The second period of time is about 3 seconds to about 5 seconds, for example 3.5 seconds. The quantity of cycles is about 700 to about 1500.

In one or more embodiments, during the first deposition process of operation 240a the molybdenum-containing precursor is flowed into the processing region at a precursor gas flow rate of about 100 standard cubic-centimeters per minute (SCCM) to about 2,000 SCCM. The reducing agent is flowed into the processing region at a reducing agent gas flow rate of about 6,000 to about 21,000 SCCM. The carrier gas is flowed into the processing region at a carrier gas flow rate of about 9,000 to about 15,000 SCCM. Additionally, during the first deposition process of operation 240a, the processing region (i.e., the processing chamber) is maintained at a chamber pressure of about 10 Torr to about 20 Torr. The processing region may also be maintained at a chamber temperature of about 325 °C to about 400 °C.

As noted above, a molybdenum metal fill material 310 is used as replacement for other metal fill materials, such as tungsten, due to the lower resistance of molybdenum. However, as also noted above, the molybdenum-containing precursor has a corrosive property that can cause corrosion on the electrical connection 303 and/or the metal layer 307. Advantageously, because the first deposition process uses a molybdenum-containing precursor gas flow duration that is shorter than the reducing agent/carrier gas flow duration and/or flows the molybdenum-containing precursor at a low flux (due to the first precursor gas flow rate), the first deposition process prevents corrosion of the electrical connection 303 and/or the metal layer 307 while still achieving the benefit of the lower resistance provided by the metal fill material 310. Furthermore, the first deposition process allows for the metal fill material 310 to fill different features of different sizes at the same height.

In one or more embodiments, during operation 240a (the first deposition process), the ratio of the precursor gas flow rate to the chamber pressure is about 5:1 to about 200:1. The ratio of precursor gas flow rate to the chamber temperature is about 1:4 to about 80:13. The ratio of the precursor gas flow rate to the reducing agent gas flow rate is about 1:210 to about 1:3.

On the other hand, the second deposition process (operation 240b) includes any suitable deposition process described above. In one example, the second deposition process includes depositing the metal fill material 310 using a cyclical CVD process including concurrently flowing (co-flowing) the molybdenum-containing precursor gas, the reducing agent, and the carrier gas into a processing region and exposing the semiconductor device structure 300 thereto.

During each cycle of the second deposition process, the flux of the molybdenum-containing precursor gas is changed between a low flux and a high flux by changing the ampoule temperature between a first ampoule temperature and a second ampoule temperature, respectively, while the chamber pressure of the processing region remains constant. This is described in more detail below.

In the same manner described above, during the second deposition process, the metal fill material 310 fills feature 306 from the nucleation layer 311, continuing upward to the top of the dielectric layer 309. In some embodiments, the metal fill material 310 may only partially fill feature 306.

In one or more embodiments, in the same manner as the first deposition process, the second deposition process includes repeating cycles of co-flowing the molybdenum-containing precursor gas, the reducing agent, and the carrier gas. Stated differently, during each cycles of the second deposition the molybdenum-containing precursor, the reducing agent, and the carrier gas are each flowed into the processing region during the first period of time, and only the reducing agent and the carrier gas are flowed into the processing region during the second period of time. However, during each cycle (the first period of time) of the second deposition process, the ampoule temperature (and therefore the flux of the molybdenum-containing precursor) is changed between the first ampoule temperature and the second ampoule temperature, which is greater than the first ampoule temperature. The first ampoule temperature is from about 55 °C to about 65 °C and the second ampoule temperature is from about 65 °C to about 75 °C.

Additionally, during the second deposition process of operation 240b, the processing region (i.e., the processing chamber) is maintained at the chamber pressure and the chamber temperature.

As noted above, the flow of the molybdenum-containing precursor gas is changed between the first ampoule temperature and the second ampoule temperature. Advantageously, because the second deposition process uses a molybdenum-containing precursor gas flow duration that is shorter than the reducing agent/carrier gas flow duration and/or switches from a low flux to a high flux (i.e., changes ampoule temperatures), the second deposition process prevents corrosion of the electrical connection 303 and/or the metal layer 307 while still filling the feature with a single grain metal fill material 310 and achieving the benefit of the lower resistance provided by the metal fill material 310.

In one or more embodiments, during operation 240b (the second deposition process), the ratio of the first ampoule temperature to the second ampoule temperature is about 11:13 to about 1:1. The ratio of the first ampoule temperature to the reducing agent gas flow rate is about 11:4200 to about 13:1200. The ratio of the second ampoule temperature to the reducing agent gas flow rate is about 13:4200 to about 1:80. The ratio of first ampoule temperature to the chamber pressure is about 11:4 to about 13:2. The ratio of second ampoule temperature to the chamber pressure is about 13:4 to about 15:2. The ratio of the first ampoule temperature to the chamber temperature is about 11:80 to about 1:5. The ratio of the second ampoule temperature to the chamber temperature is about 13:80 to about 3:13.

While the foregoing is directed to embodiments of the invention, other and further embodiments of the invention may be devised without departing from the basic scope thereof, and the scope thereof is determined by the claims that follow.

What is claimed is:

1. A method comprising:
forming a nucleation layer on at least one electrical connection formed in a feature formed within a dielectric layer of a semiconductor device structure;
forming a metal fill material over the nucleation layer and within the feature using a deposition process comprising:
flowing a molybdenum-containing precursor at a precursor gas flow rate, a reducing agent at a reducing agent gas flow rate, and a carrier gas at a carrier gas flow rate into a processing region during a first period of time; and
stopping the flowing of the molybdenum-containing precursor after the first period of time while continuing the flowing of the reducing agent and the carrier gas during a second period of time.

2. The method of claim 1, wherein a ratio between the precursor gas flow rate and the reducing agent gas flow rate is about 1:210 to about 1:3

3. The method of claim 1, wherein the precursor gas flow rate is about 100 SCCM to about 2,000 SCCM.

4. The method of claim 1, wherein a ratio of the precursor gas flow rate to a chamber temperature of the processing region is about 1:4 to about 80:13.

5. The method of claim 1, wherein a ratio of the precursor gas flow rate to a chamber pressure of the processing region is about 5:1 to about 200:1.

6. The method of claim 1, wherein the nucleation layer comprises molybdenum, and the metal fill material comprises molybdenum.

7. The method of claim 1, wherein the molybdenum-containing precursor comprises molybdenum pentachloride (MoCl₅).

8. The method of claim 1, wherein the first period of time is about 0.3 seconds to about 4.5 seconds.

9. The method of claim 1, wherein the second period of time is about 3 seconds to about 5 seconds.

10. The method of claim 1, wherein the processing region is maintained at a constant chamber pressure.

11. A method comprising:
forming a nucleation layer on at least one electrical connection formed in a feature formed within a dielectric layer of a semiconductor device structure;
forming a metal fill material over the nucleation layer and within the feature using a deposition process comprising:
flowing a molybdenum-containing precursor, a reducing agent at a reducing agent gas flow rate, and a carrier gas at a carrier gas flow rate into a processing region during a first period of time, wherein flowing the molybdenum-containing precursor comprises switching between a first ampoule temperature and a second ampoule temperature while the processing region is maintained at a constant chamber pressure, and the second ampoule temperature is greater than the first ampoule temperature; and
stopping the flowing of the molybdenum-containing precursor after the first period of time while continuing the flowing of the reducing agent and the carrier gas during a second period of time.

12. The method of claim 11, wherein the first ampoule temperature is about 55°C to about 65°C and the second ampoule temperature is about 65°C to about 75°C.

13. The method of claim 11, wherein a ratio of the first ampoule temperature to the second ampoule temperature is about 11:13 to about 1:1.

14. The method of claim 11, wherein a ratio of the first ampoule temperature to a chamber temperature of the processing region is about 11:80 to about 1:5, and a ratio of the second ampoule temperature to the chamber temperature is about 13:80 to about 1:3.

15. The method of claim 11, wherein a ratio of the first ampoule temperature to a chamber pressure of the processing region is about 11:4 to about 13:2, and a ratio of the second ampoule temperature to the chamber pressure is about 13:4 to about 15:2.

16. The method of claim 11, wherein a ratio of the first ampoule temperature to the reducing agent gas flow rate is about 11:4200 to about 13:1200.

17. The method of claim 11, wherein a ratio of the second ampoule temperature to the reducing agent gas flow rate is about 13:4200 to about 13:1200.

18. The method of claim 11, wherein the nucleation layer comprises molybdenum and the metal fill material comprises molybdenum.

19. The method of claim 11, wherein the molybdenum-containing precursor comprise molybdenum pentachloride (MoCl₅).

20. The method of claim 11, wherein the first period of time is about 0.3 seconds to about 4.5 seconds, and the second period of time is about 3 seconds to about 5 seconds.
